(19) United States
(12) Patent Application Publication
(10) Pub. No.: US 2009/0120584 A1
(43) Pub. Date: May 14, 2009

(54) COUNTER-BALANCED SUBSTRATE SUPPORT

(75) Inventors: Dmitry Lubomirsky, Cupertino, CA (US); Toan Q. Tran, San Jose, CA (US); Lun Tsuei, Mountain View, CA (US); Manuel A. Hernandez, Santa Clara, CA (US); Kirby H. Floyd, San Jose, CA (US); Ellie Y. Yieh, San Jose, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/059,820

(22) Filed: Mar. 31, 2008

Related U.S. Application Data
(60) Provisional application No. 60/986,511, filed on Nov. 8, 2007.

(51) Int. Cl. C23F 1/08; B05C 13/00; B05C 15/00; H01L 21/677; B05C 21/00

(52) U.S. Cl. 156/345.51; 118/500; 118/50; 414/805

(57) ABSTRACT

A semiconductor processing system is described. The system includes a processing chamber having an interior capable of holding an internal chamber pressure below ambient atmospheric pressure. The system also includes a pumping system coupled to the chamber and adapted to remove material from the processing chamber. The system further includes a substrate support pedestal, where the substrate support pedestal is rigidly coupled to a substrate support shaft extending through a wall of the processing chamber. A bracket located outside the processing chamber is provided which is rigidly and sometimes rotatably coupled to the substrate support shaft. A motor coupled to the bracket can be actuated to vertically translate the substrate support pedestal, shaft and bracket from a first position to a second position closer to a processing plate. A piston mounted on an end of the bracket provides a counter-balancing force to a tilting force, where the tilting force is generated by a change in the internal chamber pressure and causes a deflection in the position of the bracket and the substrate support. The counter-balancing force reduces the deflection of the bracket and the substrate support.

### CROSS-REFERENCES TO RELATED APPLICATIONS

This application claims the benefit of U.S. Provisional Application No. 60/986,511, filed Nov. 8, 2007. This application is also related to U.S. Pat. No. 6,935,466, issued Aug. 30, 2005. The entire contents of the provisional patent application and patent are herein incorporated by reference for all purposes.

### FIELD OF THE INVENTION

The present invention relates to manufacturing technology solutions involving equipment, processes, and materials used in the deposition, patterning, and treatment of thin-films and coatings, with representative examples including (but not limited to) applications involving: semiconductor and dielectric materials and devices, silicon-based wafers and flat panel displays (such as TFTs).

### BACKGROUND OF THE INVENTION

A conventional semiconductor processing system contains one or more processing chambers and a means for moving a substrate between them. A substrate may be transferred between chambers by a robotic arm which can extend to pick up the substrate, retract and then extend again to position the substrate in a different destination chamber. Each chamber has a pedestal or some equivalent way of supporting the substrate for processing.

A pedestal can be a heater plate in a processing chamber in which the heater plate heats a substrate supported on the plate. The substrate may be transported into the chamber through a slit valve by a transport robot which positions the substrate above the pedestal. A lift mechanism which may include a plurality of lift fingers, can be raised within the chamber until the lift fingers engage the underside of the substrate and lift the substrate from the robot arm. Once the robot arm is withdrawn from the chamber, lowering the lift mechanism below the pedestal transfers the weight of the substrate to the support surfaces of the pedestal.

After the substrate is placed on the pedestal, lift fingers may be used to initially support the substrate and then may descend below the support surface to a retracted position. The substrate can then be held by a mechanical or electrostatic means which secures the substrate to the pedestal. One or more semiconductor fabrication process steps are performed in the chamber, such as annealing the substrate or depositing or etching films on the substrate. After completion of the process steps, the lift fingers may be raised to elevate the substrate above the pedestal so that the substrate can be removed from the chamber by the robot arm.

Some chambers will employ a cooling plate positioned above the pedestal to cool the substrate prior to removing the substrate from the chamber. The lift mechanism may be used to lift the substrate from the pedestal following a process wherein the substrate temperature is raised, and to position the substrate adjacent to the cooling plate to facilitate cooling of the substrate prior to removal of the substrate from the chamber. Contact between the substrate and the cooling plate should be prevented to avoid damaging the substrate and to protect the chamber from particulates. Accordingly, the extension of the lift fingers is usually carefully controlled. To establish this control, the lift fingers are usually aligned with respect to a chamber interior surface to provide a baseline or “zero” location for the lift mechanism control system. A calibration is typically done periodically to adjust the uniformity of the gap between the extended lift pins and the cooling plate to improve the cooling uniformity during a substrate cooling process.

But cooling uniformity is just one application that relies on the uniformity of a substrate-plate spacing. A reduction in the tilt of a substrate surface can also result in an improvement in the uniformity of parameters associated with an etch or deposition process. In affiliation with these processes it is often desirable to align the substrate with the pins in the retracted position and the substrate supported by the pedestal because this more closely simulates the actual process configuration. Deposition processes operate at a wide range of process pressures, introducing another parameter which impacts substrate alignment.

Conventional thermal CVD processes supply reactive gases to the substrate surface where the heat from the surface induces chemical reactions to produce a film. These CVD processes are often used to deposit dielectric films and achieve viable growth rates by maintaining a relatively high pressure in the process chamber. Exemplary processes include atmospheric pressure CVD (APCVD) and sub atmospheric CVD (SACVD) though the process pressure can even be above atmospheric pressure. Other acronyms may be used to describe processes with similar process pressures but are named to highlight a specific chemistry or capability.

Such processes use higher process pressures than plasma assisted processes to compensate for the lower reactivity of the gas. The higher pressures introduce a more significant stress on chamber components and even though a semiconductor processing system is a relatively solid appliance, an internal pressure change of over a hundred Torr results in non-negligible adjustments in positions and tilting angles of some chamber components. Different recipes using different process pressures may be run on the same chamber changing the substrate tilt more frequently than a viable preventative maintenance (PM) schedule would allow.

Further complicating matters, the use of high pressure processes to fill gaps contributed to the use of multi-step processes wherein earlier steps cater to filling gaps without leaving voids. Later steps may sacrifice gap-filling characteristics for higher growth rates. These multi-step processes can be desirable for other reasons including the improvement of adhesion when depositing high stress films. Regardless of the motivation, these different steps may involve differences in substrate position and temperature. They may also involve mid-process changes in reactive component gases present in the process chamber, reaction stoichiometry and process pressure. Mid-process pressure variations may result in a variation in the substrate tilt and gives rise to a need for a tilt adjustment during processing.

There accordingly remains a need in the art for a mechanism and method capable of adjusting the substrate tilt angle more frequently and even during substrate processing.

### BRIEF SUMMARY OF THE INVENTION

The present invention relates to a counter-balancing apparatus for compensating for a tilt caused by a difference in pressure inside a semiconductor processing system. A process-induced tilt occurs between the substrate support assembly and many processing chambers when the internal pressure is varied. This tilt can significantly impact process uniformity across a substrate surface.

The tilt can be counter-balanced by introducing a compensating force which opposes the tilt caused by the change in a processing pressure. In embodiments, the compensating force is created by a controlled pressure in a compartment, rigidly attached to the substrate support, which pushes a piston and a tilt inducing extension into a wall of the processing chamber. In alternate embodiments, the force is applied to a stand-off plate rigidly attached to the processing chamber.

The counter-balancing apparatus may be used on a variety of semiconductor processing chambers. The apparatus is useful for many steps in a processing sequence which benefit from a uniform gap between the substrate surface and a processing plate. Two examples include gas distribution plates used for chemical vapor deposition and cooling plates used after substrate heating. In some processing applications the substrate will be supported by a pedestal and in others it will be supported by lift pins which lift the substrate above the pedestal.

This counter-balancing apparatus may be adapted for substrate deposition chambers operating with process pressures ranging from well below atmospheric pressure to, in some cases, higher than atmospheric pressure. In these chambers the substrate support pedestal may be raised and lowered with respect to an overlying showerhead or nozzle array that directs the flow of deposition gases onto the substrate surface. Changes in the pressure of the deposition chamber can create a tilting force that gets transmitted down the substrate support shaft to the motor and heater which may be coupled to the shaft by a bracket outside the deposition chamber. This force can cause the bracket, heater, motor, shaft, substrate support surface, and the substrate itself to deflect away from parallel alignment with the showerhead or nozzle array. A piston whose main body is attached to the bracket and whose plunger top contacts the outside surface of the chamber (or a structure fixed to the chamber) generates a counter-balancing force in the opposite direction of the tilting force thereby reducing (sometimes essentially eliminating) the degree of tilt by the substrate support equipment.

For chambers that use lift pins to raise a substrate off a substrate pedestal towards a processing plate (e.g. a cooling plate useful following a period of heating), a compartment may be mounted around the pistons that translate the pins up and down inside the processing chamber. The bottom ends of these pistons face opposite the chamber and are exposed within an adjustably pressurized compartment. The compartment that surrounds the bottom portion of the pistons allows the pressure on the bottom ends of the pistons to be set at pressures other than the relatively constant ambient air pressure. The compartment pressure can change dynamically with a change in the chamber pressure to help move the lift pins from a low to high (or high to low) position, and may do so without causing the supported substrate to tilt.

Embodiments of the invention include semiconductor processing systems having a processing chamber with an interior capable of holding an internal chamber pressure below (or above) ambient atmospheric pressure, and a pump coupled to said chamber and adapted to remove material from the processing chamber. The system may also include a substrate support assembly adapted to support a substrate, and an alignment member disposed above the substrate support and having an alignment surface. A plurality of lift pins are present in embodiments, each of which has an engagement surface adapted to approach or engage the alignment surface. The substrate support assembly further includes a shaft extending through a wall of the processing chamber. A bracket located outside the processing chamber is provided which is coupled to a heater that is thermally coupled to the substrate support though the shaft. A motor coupled to the bracket can be actuated to vertically translate the heater and the shaft from a first position to a second position closer to the gas manifold. A piston mounted on an end of the bracket provides a counter-balancing force to a tilting force, where the tilting force is generated by a change in the internal chamber pressure and causes a deflection in the position of the bracket and the substrate support. The counter-balancing force reduces the deflection of the bracket and the substrate support.

Embodiments of the invention also include a semiconductor processing system with a processing chamber having a gas manifold to transport deposition materials to a substrate.

Embodiments of the invention still further include methods to reduce a tilting deflection of a substrate support during a change in pressure of a processing chamber of a semiconductor processing system. The methods may include the steps of generating a tilting force by the change in the internal pressure of the processing chamber, and generating a counter-balancing force in a piston coupled to the processing chamber. The counter-balancing force has the opposite direction as the tilting force and reduces the tilting deflection of the substrate support.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 shows a cut-away schematic view of a counter-balancing apparatus mated to a semiconductor processing chamber;

FIG. 2 shows the deflection of substrates in a semiconductor processing chamber with and without the activation of a counter-balancing piston air cylinder according to embodiments of the invention;

FIG. 3 shows semiconductor substrate maps of dielectric film thickness measurements grown in a semiconductor processing system equipped with a counter-balanced substrate support apparatus according to embodiments of the invention;

FIG. 4A shows a simplified representation of a semiconductor processing system according to embodiments of the present invention;

FIG. 4B shows a simplified representation of the user interface for a semiconductor processing system in relation to a processing chamber in a multi-chamber system; and

FIG. 4C shows a simplified diagram of a gas panel and supply lines in relation to a processing chamber.

### DETAILED DESCRIPTION OF THE INVENTION

Implementations of the present invention include a counter-balancing apparatus for compensating for a tilt caused by a difference in pressure inside a processing chamber compared to the external pressure. This latter tilt caused predominantly by the process pressure will be referred to as a process-induced tilt and the term compensating tilt will be used to describe the contribution of the counter-balancing apparatus. The goal is to lower the net tilt of the substrate surface which can be beneficial to the outcome of many processes. In embodiments, the uniformity of an etch or deposition process may be more uniform or a substrate cooling process may be shortened through the use of the compensating apparatus described herein. Methods of using the counter-balancing apparatus are also within the scope of the invention and involve the magnitude or sequence of magnitudes of the compensating tilt or compensating force.

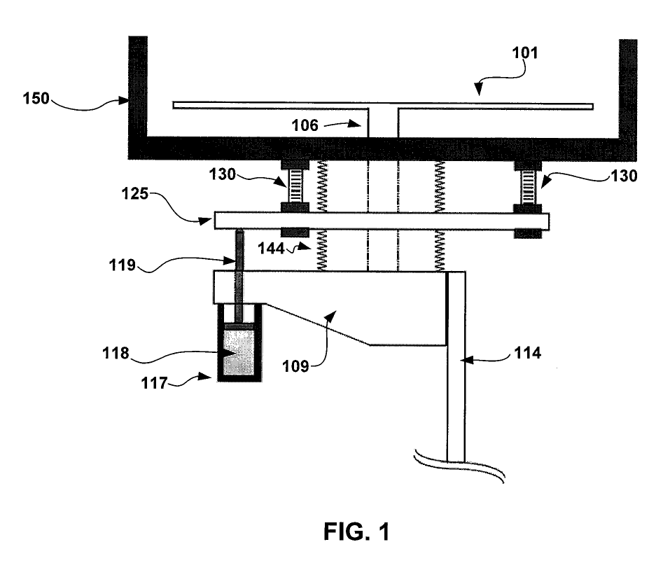

In order to better appreciate and understand the present invention, reference is made to FIG. 1 which is a cutaway schematic of a counter-balancing apparatus configured with a semiconductor processing chamber 150. Upon being transferred into the chamber, a substrate is supported on a surface such as a pedestal 101 which is rigidly coupled to a substrate support shaft 106. In embodiments, the pedestal is configured to supply heat to the substrate. The shaft, in turn, is rigidly attached to a substrate support bracket 109 and a support member 114 which may be on a translation stage configured to move vertically in the figure. A stainless steel bellows provides a non-rigid coupling between the chamber 150 and the substrate support bracket 109, to provide a processing seal between the interior and exterior of the processing chamber.

In order to define the current use of rigid it should be noted that, two rigidly attached components are expected to respond similarly when an tilting force is applied. It is also important to note that components can be rigidly attached but still allow rotation. For instance, the substrate support shaft 106 is often rotatably coupled with the substrate support bracket 109, yet both will tilt similarly in response to an off-center external force. A means for adjusting a tilt-inducing force (shown in this figure as an air cylinder 117,118) and a tilt-inducing extension 119 are mated to the substrate support bracket and serve to apply a compensating force to the processing chamber which acts to rotate the substrate support assembly (including the support member 114, pedestal 101, shaft 106 and bracket 109) counterclockwise in the figure relative to the semiconductor processing chamber and any rigidly attached components.

In embodiments, the tilt-inducing force is created by a pneumatic actuator with a pneumatic housing 117 and a region 118 of variable pneumatic pressure used to drive the tilt-inducing extension with a predictable force. A hydraulic mechanism may be used in alternate embodiments to create the same effect.

The tilt-inducing extension may apply a force directly to the processing chamber or it may, as shown in FIG. 1, apply the force to a rigid attachment to the processing chamber. The rigid attachment may be a stand-off plate 125 supported by stand-offs 130 configured to provide support so a tilting force applied to the stand-off plate will have a similar effect to applying the force more directly to the processing chamber.

The strength of these structural components is important and in view of that, they should be designed to avoid significant flexing when stresses are applied. This includes the use of relatively thick and well separated stand-offs when a stand-off plate is employed. It is best to use three or more stand-offs when possible. Structural rigidity and the ability to tightly control the compensating force will improve the reproducibility of the compensating tilt which is important for reliably lowering the net tilt of the substrate surface during processing.

The alignment of the top of a substrate and the chamber is usually done by monitoring and adjusting the uniformity of the gap between a substrate placed on the pedestal and a plate above the substrate, rigidly coupled to the processing chamber. The plate may be a gas distribution plate as in CVD or a cooling plate used in a variety of chambers equipped with annealing functionality. For CVD the pedestal itself may be adjusted to minimize the variation of the gap across two crossing paths. In the case of a cooling plate used after annealing, a substrate is often raised using lift pins to approach the cooling plate. The cooling plate gap variation can be controlled by adjusting the pedestal too, but the extension of the lift pins can be adjusted individually to achieve a similar effect.

During a calibration procedure the substrate pedestal 101 may be aligned relative to a plate with the chamber vented (same pressure inside as outside the chamber) or at a reduced process pressure. The pressure present within the process chamber during calibration will alter the compensating force which needs to be applied at a given process pressure. When the calibration is done with the chamber vented, the subsequent reduction of the internal pressure during processing will reduce the force applied by the gas downward on the substrate support bracket 109. This reduction in internal pressure will therefore result in a clockwise rotation of the substrate support assembly relative to the chamber itself in the absence of a compensating force created by the tilt-inducing extension 119. Though the magnitude of this rotation may be small measured in degrees, this process-induced tilt can result in several tens of thousandths of an inch variation in the observed gap across the surface of a 300 mm diameter substrate (a 300 mm wafer). This level of variation has been found to significantly affect process results.

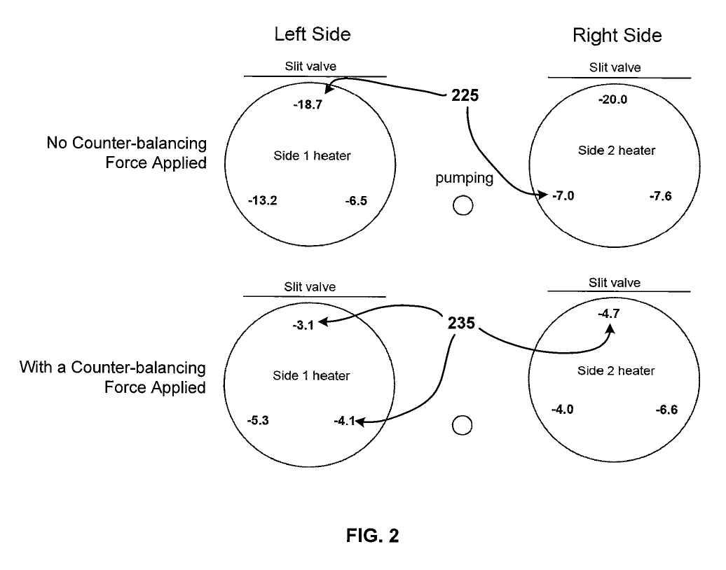

A pedestal was aligned by traditional means to a chamber surface with an internal chamber pressure of 200 Torr in preparation for the measurements shown in FIG. 2. Following the calibration, the positions of three locations on the pedestal were noted and then the pressure inside the chamber was raised to 600 Torr reproducing a typical change in process pressures in some CVD recipes which fill gaps at the lower pressure and add film thickness more quickly at the higher pressure. Mechanical height measurements are shown in thousandths of an inch at the three locations following the increase in pressure.

The upper wafer maps were taken with no compensating force applied between the wafer support assembly and the processing chamber. The three numbers are negative indicating that the impact of the additional 400 Torr is to push the wafer support assembly downward. The maximum difference among the three numbers (about 0.012″) shows the process-induced tilt caused the change in internal pressure. The lower wafer maps were taken with an tilt-inducing force applied (created by 30 psi in the pneumatic region 118) to compensate for the process-induced tilt caused by the process pressure increase of 400 Torr. The maximum difference among the three numbers has been reduced to near 0.002″, which represents a five-fold improvement in alignment. The height of the pedestal (and therefore a loaded wafer) is still going to be lower by about 0.005″ but since the surfaces will be aligned, this additional gap can be accommodated by other means if necessary.

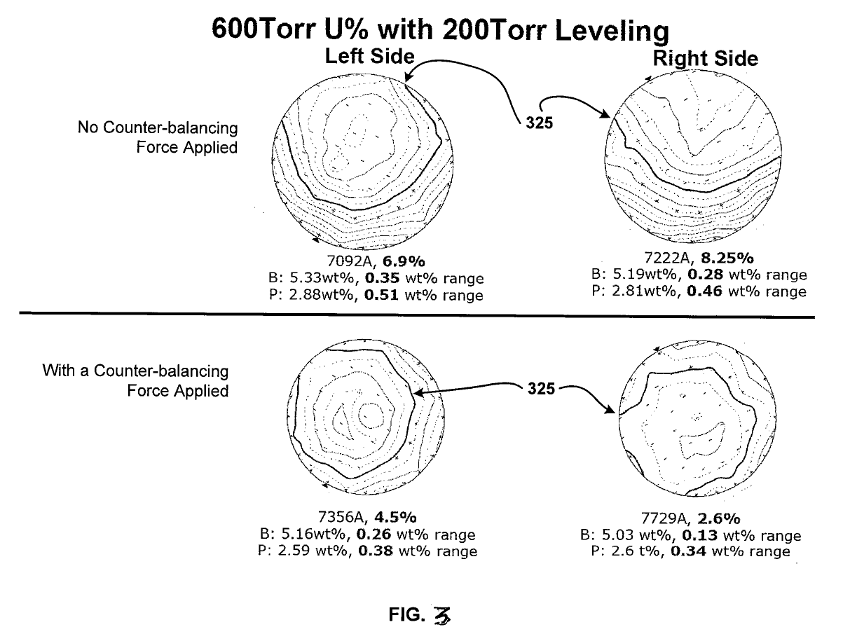

A representative result from the use of embodiments of the present invention are shown in FIG. 3. Shown are 49-point wafer maps showing deviations of the thickness of glass films about their mean value. These particular films contain minority concentrations of boron and phosphorous and are known in the art as “BPSG” films. The solid lines 325 represent the approximate locations where each BPSG film has a mean thickness similar to the mean of all 49 points. Other lines of constant thickness are shown for thicker and thinner values which occur near plus and minus signs, respectively. The plus and minus signs appear where an actual measurement was made. The edge exclusion during these measurements was about 3 mm.

Before deposition the wafer support assembly was leveled by conventional means while the pressure in the processing chamber was 200 Torr. The deposition of the BPSG films conducted at 600 Torr process pressure with and without a compensating force applied. The upper wafer maps were taken with no compensating force applied between the wafer support assembly and the processing chamber. Regions where the lines of constant thickness get close together indicate a larger rate of change in thickness for the upper wafer maps when compared with the lower wafer maps. The lower wafer maps were taken with a tilt-inducing force applied to compensate for a process-induced tilt caused by the process pressure of 600 Torr. The statistical deviation about the mean also gives a clear indication of the improvement. The upper wafer maps have standard deviations of 6.9% and 8.25% about their means while the lower wafer maps have substantially lower measurement deviations of 4.5% and 2.6%.

Also noted under each wafer map are the mean and standard deviation of the boron and phosphorous concentrations. These were similarly acquired at 49 points and indicate a dependence on distance of the wafer from the gas distribution plate. The films grown with the counter-balancing force exhibit reduced variation in concentration possibly due to a drop in the variation of the partial pressures of dopant-containing precursors at the substrate surface.

The discussion contained herein and the claims may discuss only one tilt-inducing extension in certain cases, however, multiple extensions can be installed. Another tilt-inducing extension in FIG. 1 may be used to tilt the substrate support assembly out of the plane of the figure and the benefits of introducing multiple extensions can be seen in the lower wafer maps of FIG. 3. The map on the left shows most clearly that the constant thickness line 325 has been centered top to bottom by the counter-balancing force. However, further adjustment would move the circular constant thickness line 325 to the right further improving the standard deviation result.

Chambers that employ lifting fingers during processing can benefit from the embodiments of the invention described in relation to FIG. 1. When the substrate is supported on lifting fingers, the substrate may have a different tilt than if it were supported on the pedestal. This may change the forces and position required of the tilt-inducing extension but the same apparatus described with reference to FIG. 1 can be used in a similar manner.

Typically, lifting fingers are used in conjunction with a cooling plate so this description will focus on that specific process without any intention of limiting the claimed subject matter. In such a process, a cooling plate is positioned above the substrate surface to cool the substrate prior to removing the substrate from the chamber. The gap should be reproducibly uniform so the cooling can proceed uniformly. This also allows the substrate to be placed more closely to the cooling plate increasing efficiency and reducing cooling time. To ensure a uniform gap, the lift fingers are usually aligned with respect to a chamber interior surface to provide a baseline or “zero” location for the lift mechanism control system. The top of the lift pins may or may not touch the cooling plate during the alignment process. A calibration is typically done periodically to adjust the uniformity of the gap between the extended lift pins and the cooling plate to improve the cooling uniformity during a substrate cooling process.

Compartments (or air cylinders) are usually mounted around the pistons to control the lift pins. The air cylinders are pressurized to move the pins up and down inside the processing chamber. The compartments that surround the pistons can be individually pressurized which allows the pressure on the bottom ends of the pistons to be set at a variety of pressures. However, the lifting fingers need to be brought up and down uniformly to avoid tilting the substrate during the lifting process which would result in touching a portion of the substrate to the cooling plate. In a preferred solution, the air cylinders are maintained at common pressures for each lift pin (possibly by connecting all the compartments together and pressurizing the combined volume). Changing the difference between the common pressure and the internal chamber pressure will help move the lift pins from a low to high (or high to low) position, and do so without causing the supported substrate to tilt. The lift fingers are aligned to the cooling plate by raising them to a position contacting or near the cooling plate with the common lift pin pressure, then a counter-balancing apparatus is used to supply a compensating force which adjusts the gaps between lift pins and the cooling plate to be more uniform.

Regardless of whether the calibration routine is being done with lift pins, a pedestal or a substrate on a pedestal, the process pressure should be maintained at a similar pressure (or pressures) to those used during processing. Multiple pressures can be used in one or more recipes, in such cases the compensating force needed to maintain a level surface should be determined for each process pressure.

Methods of using the counter-balancing apparatus are also within the scope of the invention. Aspects of these methods may include using the apparatus to calibrate the substrate tilt infrequently or on a specific schedule such as a preventative maintenance procedure. Other aspects of these methods pertain to the use of the counter-balancing apparatus during processing to set the compensating force based on the pressures requested in process recipes. The compensating force in such cases may be changed once per process step. Such an open loop operation may be improved upon by operating the apparatus based on an actual measurement of the process chamber pressure. Therein the compensating force may be modified in real time at fixed or variable intervals, possibly based on the rate of change of the measured pressure.

Quantitatively, the compensating force may be determined by a calculation which depends on the process pressure and it is possible to use either a measured value or recipe-requested value in the calculation. In other embodiments a factory defined look-up table (LUT) may be employed to calculate the amount of compensating tilt desirable for a given process pressure. The LUT or constants in the calculation may be stored in rewritable memory which would allow them to be modified in the field as part of a calibration procedure.

### Exemplary Substrate Processing System

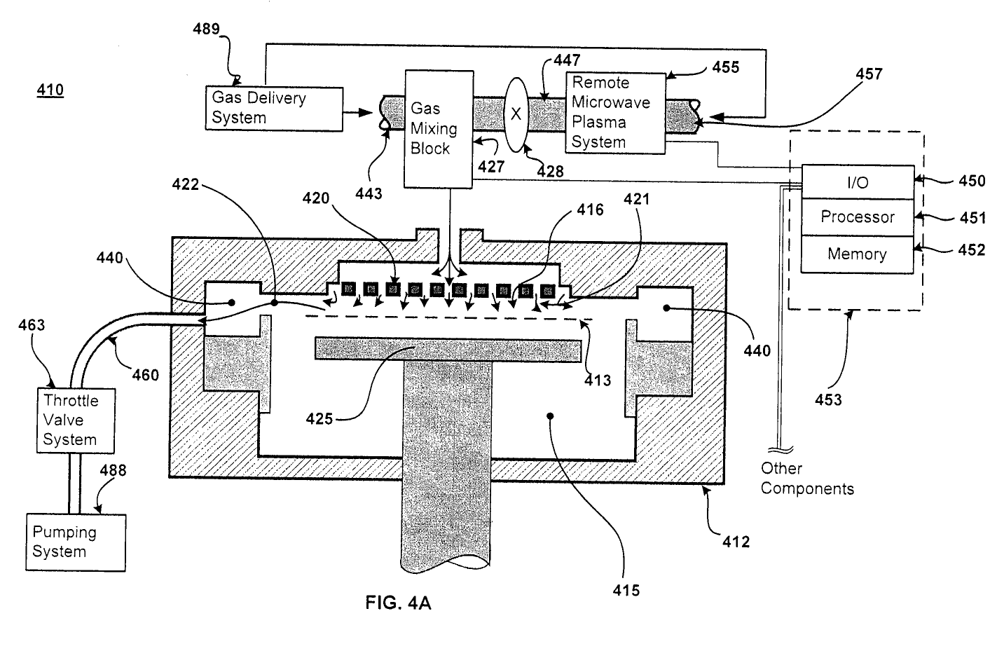

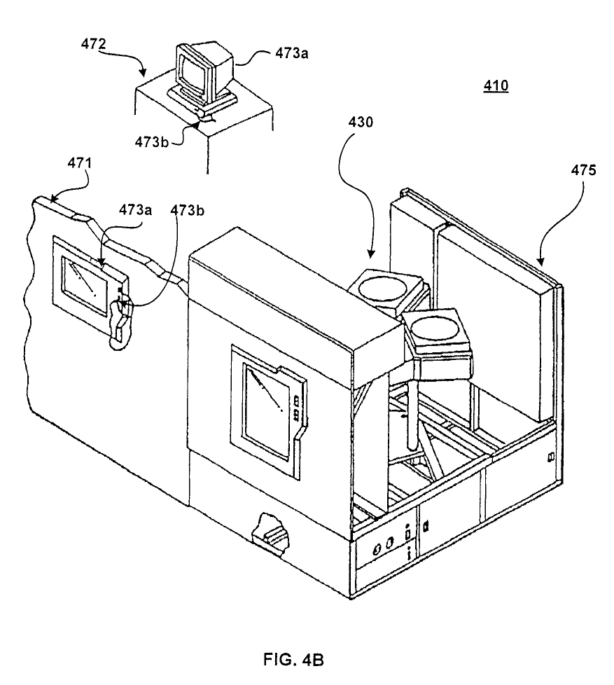

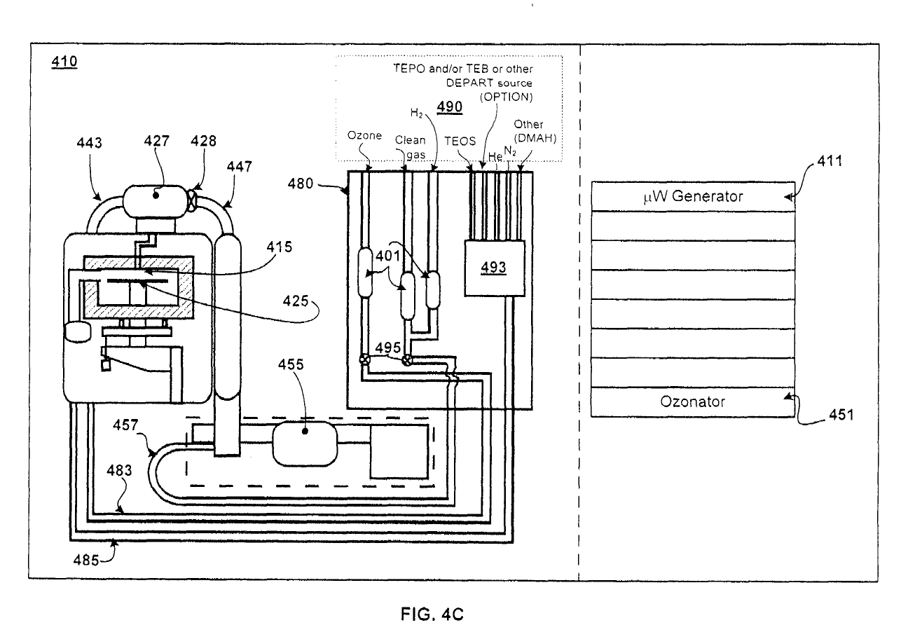

Having described modifications which may be made to and methods of using semiconductor processing systems according to embodiments of the present invention, attention is directed to FIG. 4A, which illustrates a simplified diagram of an exemplary semiconductor processing system 410. This system is suitable for performing a variety of semiconductor processing steps which may include CVD processes, as well as other processes, such as reflow, drive-in, cleaning, etching, and gettering processes. Multiple-step processes can also be performed on a single substrate without removing the substrate from the chamber. Representative major components of the system include a processing chamber 415 that receives process and other gases from a gas delivery system 489, pumping system 488, a remote plasma system (RPS) 455, and a control system 453. These and other components are described below in order to understand the present invention.

The semiconductor processing system 410 includes an enclosure assembly 412 housing a processing chamber 415 with a gas reaction area 416. A gas distribution plate 420 is provided above the gas reaction area 416 for dispersing reactive gases and other gases, such as purge gases, through perforated holes in the gas distribution plate 420 to a substrate (not shown) that rests on a vertically movable heater 425 (which may also be referred to as a substrate support pedestal). The heater 425 can be controllably moved between a lower position, where a substrate can be loaded or unloaded, for example, and a processing position closely adjacent to the gas distribution plate 420, indicated by a dashed line 413, or to other positions for other purposes, such as for an etch or cleaning process. A center board (not shown) includes sensors for providing information on the position of the substrate.

In some embodiments, the gas distribution plate 420 may be of the variety described in previously-incorporated U.S. Pat. No. 6,793,733. These plates improve the uniformity of gas disbursement at the substrate and are particularly advantageous in deposition processes that vary gas concentration ratios. In some examples, the plates work in combination with the vertically movable heater 425 (or movable substrate support pedestal) such that deposition gases are released farther from the substrate when the ratio is heavily skewed in one direction (e.g., when the concentration of a silicon-containing gas is small compared to the concentration of an oxidizer-containing gas) and are released closer to the substrate as the concentration changes (e.g., when the concentration of silicon-containing gas in the mixture is higher). In other examples, the orifices of the gas distribution plate are designed to provide more uniform mixing of the gases.

The heater 425 includes an electrically resistive heating element (not shown) enclosed in a ceramic. The ceramic protects the heating element from potentially corrosive chamber environments and allows the heater to attain temperatures up to about 800° C. In an exemplary embodiment, all surfaces of the heater 425 exposed within the processing chamber 415 are made of a ceramic material, such as aluminum oxide (Al₂O₃ or alumina) or aluminum nitride.

Reactive and carrier gases are supplied through the supply line 443 into a gas mixing box (also called a gas mixing block) 427, where they are preferably mixed together and delivered to the gas distribution plate 420. The gas mixing block 427 is preferably a dual input mixing block coupled to a process gas supply line 443 and to a cleaning/etch gas conduit 447. A valve 428 operates to admit or seal gas or plasma from the gas conduit 447 to the gas mixing block 427. The gas conduit 447 receives gases from an RPS 455, which has an inlet 457 for receiving input gases. During deposition processing, gas supplied to the plate 420 is vented toward the substrate surface (as indicated by arrows 421), where it may be uniformly distributed radially across the substrate surface, typically in a laminar flow.

Purging gas may be delivered into the processing chamber 415 through the plate 420 and/or an inlet port or tube (not shown) through a wall (preferably the bottom) of enclosure assembly 412. The purging gas flows upward from the inlet port past the heater 425 and to an annular pumping channel 440. An exhaust system then exhausts the gas (as indicated by arrows 422) into the annular pumping channel 440 and through an exhaust line 460 to a pumping system 488, which includes one or more vacuum pumps. Exhaust gases and entrained particles are drawn from the annular pumping channel 440 through the exhaust line 460 at a rate controlled by a throttle valve system 463.

The RPS 455 can produce a plasma for selected applications, such as chamber cleaning or etching native oxide or residue from a process substrate. Plasma species produced in the remote plasma system 455 from precursors supplied via the input line 457 are sent via the conduit 447 for dispersion through the plate 420 to the processing chamber 415. Precursor gases for a cleaning application may include fluorine, chlorine, and other reactive elements. The RPS 455 also may be adapted to deposit plasma enhanced CVD films by selecting appropriate deposition precursor gases for use in the RPS 455.

The system controller 453 controls activities and operating parameters of the deposition system. The processor 451 executes system control software, such as a computer program stored in a memory 452 coupled to the processor 451. The memory 452 typically consists of a combination of static random access memories (cache), dynamic random access memories (DRAM) and hard disk drives but of course the memory 452 may also consist of other kinds of memory, such as solid-state memory devices. In addition to these memory means the semiconductor processing system 410 in a preferred embodiment includes a floppy disk drive, USB ports and a card rack (not shown).

The processor 451 operates according to system control software programmed to operate the device according to the methods disclosed herein. For example, sets of instructions may dictate the timing, mixture of gases, chamber pressure, chamber temperature, plasma power levels, susceptor position, and other parameters of a particular process. The instructions are conveyed to the appropriate hardware preferably through direct cabling carrying analog or digital signals conveying signals originating from an input-output I/O module 450. Other computer programs such as those stored on other memory including, for example, a USB thumb drive, a floppy disk or another computer program product inserted in a disk drive or other appropriate drive, may also be used to operate the processor 451 to configure the semiconductor processing system 410 for varied uses.

The processor 451 may have a card rack (not shown) that contains a single-board computer, analog and digital input/output boards, interface boards and stepper motor controller boards. Various parts of the processing system 410 conform to the Versa Modular European (VME) standard which defines board, card cage, and connector dimensions and types. The VME standard also defines the bus structure having a 16-bit data bus and 24-bit address bus.

The embodiment disclosed herein relies on direct cabling and a single processor 451. Alternative embodiments comprising multi-core processors, multiple processors under distributed control and wireless communication between the system controller and controlled objects are also possible.

FIG. 4B is a simplified diagram of a user interface in relation to the semiconductor processing chamber 430. The semiconductor processing system 410 includes one chamber of a multichamber system. Substrates may be transferred from one chamber to another for additional processing. In some cases the substrates are transferred under vacuum or a selected gas. The interface between a user and the processor is via a CRT monitor 473a (which can also be a flat panel monitor) and a pointing device 473b (which can be a light pen). A mainframe unit 475 provides electrical, plumbing, and other support functions for the processing system 410. Exemplary mainframe units compatible with the illustrative embodiment of the semiconductor processing system are currently commercially available as the PRECISION 5000™, the CENTURA 5200™, and the PRODUCER SE™ systems from APPLIED MATERIALS, INC. of Santa Clara, Calif.

In some embodiments two monitors 473a are used, one mounted in the clean room wall 471 for the operators, and the other behind the wall 472 for the service technicians. Both monitors 473a simultaneously display the same information, but only one light pen 473b is enabled. The light pen 473b detects light emitted by the CRT display with a light sensor in the tip of the pen. To select a particular screen or function, the operator touches a designated area of the display screen and pushes the button on the pen 473b. The touched area changes its highlighted color, or a new menu or screen is displayed, confirming communication between the light pen and the display screen. Of course, other devices, such as a keyboard, mouse, or other pointing or communication device, may be used instead of or in addition to the light pen 473b to allow the user to communicate with the processor.

FIG. 4C illustrates a general overview of an embodiment of the semiconductor processing system 410 in relation to a gas supply panel 480 located in a clean room. As discussed above, the CVD system 410 includes a chamber 415 with a heater 425, a gas mixing box 427 with inputs from an inlet tube 443 and a conduit 447, and RPS 455 with input line 457. As mentioned above, the gas mixing box 427 is for mixing and injecting deposition gas(es) and clean gas(es) or other gas(es) through the inlet tube 443 to the processing chamber 415.

The RPS 455 is integrally located and mounted below the chamber 415 with the conduit 447 coming up alongside the chamber 415 to the gate valve 428 and the gas mixing box 427, located above the chamber 415. Plasma power generator 411 and ozonator 451 are located remote from the clean room. Supply lines 483 and 485 from the gas supply panel 480 provide reactive gases to the gas supply line 443. The gas supply panel 480 includes lines from gas or liquid sources 490 that provide the process gases for the selected application. The gas supply panel 480 has a mixing system 493 that mixes selected gases before flow to the gas mixing box 427. In some embodiments, gas mixing system 493 includes a liquid injection system for vaporizing reactant liquids such as tetraethylorthosilicate (“TEOS”), triethylborate (“TEB”), and triethylphosphate (“TEPO”). Vapor from the liquids is usually combined with a carrier gas, such as helium. Supply lines for the process gases may include (i) shut-off valves 495 that can be used to automatically or manually shut off the flow of process gas into line 485 or line 457, and (ii) liquid flow meters (LFM) 401 or other types of controllers that measure the flow of gas or liquid through the supply lines.

As an example, a mixture including TEOS as a silicon source may be used with gas mixing system 493 in a deposition process for forming a silicon oxide film. The TEPO is a liquid source that may be vaporized by conventional boiler-type or bubbler-type hot boxes. However, a liquid injection system is preferred as it provides greater control of the volume of reactant liquid introduced into the gas mixing system. The liquid is typically injected as a fine spray or mist into the carrier gas flow before being delivered to a heated gas delivery line 485 to the gas mixing block and chamber. One or more sources, such as oxygen (O₂) or ozone (O₃) flow to the chamber through another gas delivery line 483, to be combined with the reactant gases from heated gas delivery line 485 near or in the chamber. Of course, it is recognized that other sources of dopants, silicon, and oxygen also may be used.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the lift pin” includes reference to one or more lift pins and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

The term “compensating” is used with the terms “force” and “tilt” with no implication that the process-induced tilt and the compensating tilt are equivalent in magnitude nor should it be inferred that they are in precisely opposite directions. A mere reduction in the net tilt of the substrate support pedestal can provide significant process benefits.

What is claimed is:

1. A semiconductor processing system comprising:
a processing chamber having an interior capable of holding an internal chamber pressure which can be different from the external chamber pressure;
a pumping system coupled to said chamber and adapted to remove material from the processing chamber;
a substrate support assembly comprising:
a substrate support member adapted to support a substrate inside the processing chamber;
a substrate support shaft rigidly attached to the substrate support member, wherein the substrate support shaft extends through an opening in a wall of the processing chamber; and
a substrate support bracket rigidly coupled to the substrate support shaft;
a flexible coupling connecting the substrate support assembly to the processing chamber, wherein a difference between the internal chamber pressure and the external chamber pressure results in a process-induced tilt of the substrate support assembly relative to the processing chamber; and
a tilt-inducing extension configured to apply a local adjustable force between the substrate support assembly and the processing chamber inducing a compensating tilt, wherein the local adjustable force and an adjustable force location are selected so the effect of the compensating tilt will be to reduce the magnitude of a net substrate tilt angle of the substrate support assembly relative to a processing plate inside the processing chamber.

2. The system of claim 1, wherein the net substrate tilt angle is less than about 0.05°.

3. The system of claim 1, wherein the tilt-inducing extension is configured to exert a force pushing the processing chamber and the substrate support bracket apart in the vicinity of the adjustable force location.

4. The system of claim 1, wherein the flexible coupling is a welded stainless steel bellows.

5. The system of claim 1, wherein the substrate support assembly further comprises a linear slide carriage, located outside the processing chamber, rigidly coupled to the substrate support bracket.

6. The system of claim 1, wherein the adjustable force is applied to a stand-off plate rigidly attached to the processing chamber with one or more stand-offs.

7. The system of claim 1, wherein a pressurized compartment is rigidly coupled to the substrate support assembly, an internal compartment pressure within the pressurized compartment is configured to be adjustable, and the internal compartment pressure drives a piston coupled to the tilt-inducing extension so the internal compartment pressure is essentially proportional to said local adjustable force.

8. The system of claim 7, wherein the internal compartment pressure is chosen based on the internal chamber pressure.

9. The system of claim 8, wherein the internal compartment pressure is selected from a look-up table.

10. The system of claim 7, wherein the pressurized compartment is a cylinder.

11. The system of claim 7, wherein the air-tight compartment comprises a movable bottom surface that can vertically translate to change the internal compartment volume.

12. The system of claim 7, wherein the internal chamber pressure decreases from the ambient atmospheric pressure to about 200 Torr, and the internal compartment pressure increases from ambient atmospheric pressure to about 60 psi.

13. A semiconductor processing system comprising:
a processing chamber having an interior capable of holding an internal chamber pressure which can be different from the external chamber pressure;
a pumping system coupled to said chamber and adapted to remove material from the processing chamber;
an alignment member disposed within the processing chamber and having an alignment surface;
a substrate support assembly comprising:
a substrate support member adapted to support a substrate inside the processing chamber;
a substrate support shaft rigidly attached to the substrate support member, wherein the substrate support shaft extends through an opening in a wall of the processing chamber;
a plurality of lift pins, each of which has an engagement surface adapted to engage said alignment surface, and each lift pin also having a piston, wherein the piston elevates the lift pin from a first position to a second extended position where the lift pin engagement surface engages the alignment surface; and
a substrate support bracket rigidly coupled to the substrate support shaft;
a flexible coupling connecting the substrate support assembly to the processing chamber, wherein a difference between the internal chamber pressure and the external chamber pressure results in a process-induced tilt of the substrate support assembly relative to the processing chamber; and
a tilt-inducing extension configured to apply a local adjustable force between the substrate support assembly and the processing chamber inducing a compensating tilt, wherein the local adjustable force and an adjustable force location are selected so the effect of the compensating tilt will be to reduce the magnitude of a net substrate tilt angle of a substrate when supported by said plurality of lift pins in the second extended position relative to said alignment surface.

14. The system of claim 17, wherein the adjustable force is applied to a stand-off plate rigidly attached to the processing chamber with one or more stand-offs.

15. The system of claim 17, wherein a pressurized compartment is rigidly coupled to the substrate support assembly, an internal compartment pressure within the pressurized compartment is configured to be adjustable, and the internal compartment pressure drives a piston coupled to the tilt-inducing extension so the internal compartment pressure is essentially proportional to said local adjustable force.

16. A method to reduce a tilting angle of a substrate support assembly relative to a processing plate rigidly attached to a processing chamber, the method comprising the steps of:
generating a process-induced tilt by changing the internal pressure of the processing chamber;
generating a compensating force in response to an internal chamber pressure; and
applying the compensating force between the substrate support assembly and the processing chamber at a location to reduce the tilting angle.

17. The system of claim 16, wherein the internal chamber pressure is measured with a gauge in the processing chamber.

18. The system of claim 16, wherein the internal chamber pressure is obtained from a process recipe.

19. The method of claim 16, wherein the compensating force is calculated from the internal chamber pressure.

20. The method of claim 16, wherein the compensating force is determined from a look-up table in response to the internal chamber pressure.
